(19) United States
(12) Patent Application Publication
(10) Pub. No.: US 2017/0025451 A1
(43) Pub. Date: Jan. 26, 2017

(54) Fabrication of an optoelectronic semiconductor device and integrated circuit structure

(71) Applicant: X-FAB Semiconductor Foundries AG, Erfurt (DE)

(72) Inventor: Daniel Gaebler, Ortsteil Sulzbach (DE)

(21) Appl. No.: 15/082,471

(22) Filed: Mar. 28, 2016

(30) Foreign Application Priority Data
Mar. 27, 2015 (DE) DE102015104820.5

(51) Int. Cl. H01L 27/144; H01L 31/0232; H01L 31/18; H01L 31/02

(52) U.S. Cl. CPC H01L 27/1443; H01L 31/02005; H01L 31/02327; H01L 31/18

(57) ABSTRACT

There is provided a method for fabricating an optoelectronic semiconductor device (2,27) including a layer stack (1,26) that comprises a metallization structure (7,7′) including a contact region (8,11) for electrically contacting the semiconductor device (2,27). Moreover, a dielectric layer (12) and a semiconductor layer (3) are provided. The semiconductor layer (3) comprises a functional region (6) configured as an interface for electromagnetic (visible or UV) radiation. Material in regions (17,20) above the contact region (8,11) and above the functional region (6) of the layer stack (1,26) is removed by a temporarily simultaneous etching, thereby forming two windows (24,18) for coupling the semiconductor device (2,27) to the environment, optically as well as electrically. It is an accomplishment of the invention that coupling and/or absorption losses of radiation to be analysed optically in CMOS silicon and other semiconductors is reduced at the reduced process complexity.

The invention relates to a method for fabricating an optoelectronic semiconductor device and an integrated circuit structure including a plurality of semiconductor devices.

By means of integrated circuit structures or integrated circuits (ICs) electrical circuits may be realised in a single electronic device in a compact manner. In this case, the integrated circuit structure comprises a certain circuit design that varies with respect to the required function and is additionally provided with several electrical inputs and outputs for supply and communication with the environment.

Typically, the integrated circuit structure is implemented on the basis of a plurality of semiconductor devices, such as MOSFETs, diodes, or other components. The usage of semiconductor devices is, among others, advantageous in that they may be fabricated and positioned in a large number by standardised processes, wherein the electrical characteristics of the semiconductor devices are sufficiently precisely adjusted by the type of the respectively selected manufacturing methods.

Generally, the higher the number of semiconductor devices that may be integrated in the circuit structure, the more complex and powerful a design of an integrated circuit structure will be. An important parameter in this case is the number of the individual semiconductor devices provided per unit area on a chip. Here, the individual components have to be contacted and wired within the chip, which is to be taken into consideration by the process steps for fabricating the integrated circuit structure.

During the fabrication of integrated circuit structures typically a plurality of specific layers are successively arranged above each other, each of the individual layers having a defined function associated with the purpose to be achieved by the circuit. For example, a typical layer stack comprises one or more semiconductor layers, dielectric layers, insulating layers and metallic layers. Typically, the semiconductor layers are locally doped in order to implement electrical characteristics, for instance of a transistor. The metallic layers are used for forming electrodes and wirings of a metallization structure, and in particular the dielectric layers and insulating layers serve as spacers and for insulation of the other components.

Upon fabricating integrated circuit structures including semiconductor devices these semiconductor devices may preferably be arranged according to a CMOS structure. In this case, a respective p-channel element is substantially symmetrically combined with a respective n-channel element so as to be positioned geometrically next to each other and to be controllable by common terminals. For example, logic operations may be performed by CMOS elements without requiring additional elements, such as an additional electrical resistor in the circuit structure.

Moreover, semiconductor devices and integrated circuit structures are frequently provided with optoelectronic features (or zones of influence), thereby allowing in this manner the usage of the advantages of the semiconductor technology in such applications, in which a specific coupling to the environment by electromagnetic radiation takes place. For example, light absorbing regions may be provided in a semiconductor layer. To this end, a plurality of different modules is known, for example optical sensors, UV (ultraviolet)-light sensors or photodiodes. Integrated circuit structures having optoelectronic capabilities are preferably fabricated by CMOS technology.

In order to enhance efficiency of the coupling to the environment in devices having optoelectronic regions or being sensitive it is attempted to minimize the absorption and reflective losses of the received or emitted radiation. To this end, various measures have been proposed in the prior art, such as antireflective behaviour by antireflective coatings or moth eye structures.

WO 2011/039568 A1 shows a semiconductor device having a window opening as an interface for coupling to the environment, wherein during the formation of the window opening a gate structure is used as an etch stop layer. Moreover, the application of an antireflective coating in the window is described.

US 2010/0117108 A1 illustrates how a light sensitive active area receives needle type projections endowing a surface with antireflective behaviour.

DE 10 2006 027 969 is a semiconductor device with integrated optics and comprising a surface provided with “moth eye structures”. Regarding moth eyes refer to http://www.jenoptik.com/de-Entspiegelungen-ahmen-Optik-Mottenaugen-nach accessed on May 18, 2014.

In the conventional solutions the interfaces themselves are structured or modified. For example, moth eye structures result in an increase of the surface area by which electron-hole pairs generated very closely to the surface by absorbed highly energetic photons of UV wavelengths are more likely to recombine prior to being reliably detected by a PN junction.

Moreover, by adding antireflective coatings the complexity of the layer stack to be formed increases, even more so for increasing integration density and thus, resulting therefrom, for an increasing number of wiring layers in a CMOS circuit.

It is an object of the invention to reduce coupling losses and/or absorption losses of light in CMOS silicon or other semiconductors, while maintaining process complexity as low as possible.

As a solution there are proposed a method for fabricating an optoelectronic semiconductor device and an integrated circuit structure including a plurality of semiconductor devices according to the independent claims.

One aspect of the invention relates to a method for fabricating an optoelectronic semiconductor device (claim 1). The method comprises the following steps.
Providing a layer stack including a metallization structure that comprises at least one contact region for electrically contacting the semiconductor device, at least one dielectric layer and at least one semiconductor layer, the at least one semiconductor layer having a functional region that is usable as an interface for electromagnetic radiation, for example, UV or visible light;
locally stripping or removing material from the layer stack by commonly exposing, in particular etching, the material in areas or regions above the (at least one) contact region and above the (at least one) functional region;
in this manner, a respective window for optically and electrically coupling the semiconductor device to the environment is formed. Related to the process the windows have different depths.

The common exposing and in particular etching in the areas above the (at least one) contact region and above the (at least one) functional region is temporarily simultaneous, at least at the beginning, and after terminating the exposing of the window for electrical coupling (that is, after stopping for example the etching) the window for optical coupling to the environment is still further processed, thereby forming it with increased depth. Due to this process the windows have different depths and the exposing takes place temporarily “in common” during a significant time span or occurs concurrently, however, not during the entire “predetermined” duration of the exposing.

A further aspect of the invention relates to an integrated circuit structure including a plurality of semiconductor devices and an optoelectronic interface for coupling (in) electromagnetic radiation (for instance visible light), or generally for coupling the integrated circuit structure to the environment, wherein the plurality of semiconductor devices may be produced by a method according to the preceding claims (in the sense of a product by process claim).

Moreover, one aspect of the invention relates to a semiconductor device having corresponding optoelectronic properties.

One advantage of the invention resides in the fact that in a semiconductor device or an integrated circuit structure a window to an optoelectronic functional region is formed in a particularly simple manner. In this way, improved coupling to the environment by electromagnetic radiation may be achieved, which is accomplished by using existing process steps, thereby achieving cost efficiency. This holds true especially for a CMOS process, which may remain unaffected with respect to its sequence and implementation.

The functional region of the semiconductor layer may comprise a light emitting region or a light sensitive region, in particular a UV light sensitive region. Therefore a UV window may be realised in integrated optics in a simple manner.

The invention is, however, not restricted to UV light and may be applied, in principle, to any type of semiconductor devices that include integrated optics.

According to one advantageous embodiment of the invention a circuit structure with integrated optics is produced, in which the semiconductor devices form a CMOS structure.

According to a preferred embodiment of the invention the etch method used is selective and is applied for a predefined stripping or exposure time (for example etch time), thereby terminating the etching after a time that is shorter than the predefined etch time, while the etching still continuous in the area positioned above the at least one functional region.

Preferably, to this end a mask, in particular an etch mask, is formed above the layer stack so that the exposing is performed by using the mask formed. Alternatively or additionally self adjusting methods may be applied.

The metallization structure may be integrated into the dielectric layer, thereby removing by the etching the dielectric layer above the at least one functional region more deeply compared to the area above the contact region. When a plurality of contacts and optical regions are laterally distributed, it will be referred herein to a plurality of such regions, it will be referred to at eat one region for electrical coupling and one region for optical coupling.

Moreover, the mask, in particular etch mask, may be formed by a photolithographic method.

According to a particularly advantageous embodiment an existing mask provided for exposing the contact regions may be modified so as to form the mask. Therefore, the claimed method may be accomplished by a modification of an existing mask and any additional mask layer may be avoided.

According to a further particularly advantageous embodiment a passivation layer of the layer stack is opened by the etching. In particular in a CMOS circuit reflection losses are mainly observed at two interfaces: on the one hand, at the silicon surface, that is, between the surface of the semiconductor layer and an adjacent oxide and the dielectric, respectively, and on the other hand, at the passivation layer which, being an outermost encapsulating protective layer of the CMOS circuit, has a pronounced reflective behaviour with respect to air, thereby resulting in reflection losses.

By also removing the first passivation layer in the area of the window above the optoelectronic functional region the reduction of absorption loss and reflection loss may further be optimized.

For instance, in this manner the absorption and reflection may be reduced accordingly in a conventional passivation layer made of silicon nitride and being arranged on a SiO₂ insulation layer, in particular in the UV range, in which light is increasingly absorbed. In this case it should be noted that the interface Si₃N₄/air has a substantially greater ratio of refractive indexes and therefore reflects more intensively compared to the interface SiO₂/air that is now newly formed.

The removal of the passivation layer may be accomplished in this case by modifying a mask.

According to a further embodiment of the invention, after formation of the window a further passivation layer may be applied onto the layer stack, which reaches into the areas that are exposed above the functional regions by the etching. Thereafter the further passivation later may be removed again in those areas that have been previously exposed above the contact regions by the etching.

In this manner a passivation of the optical coupling window may be accomplished, wherein the newly formed second passivation layer may be significantly thinner compared to the original first passivation layer, resulting in low absorption losses.

The invention is not restricted to specific types and shapes of metallization structures. For example, according to one embodiment of the invention preferably a layer stack having a metallization structure with multilayer wiring is provided.

Moreover, the window formed above the functional region may have a lateral extension at least in one direction that is greater by a predefined factor or a predefined amount than the lateral extension of the functional region.

According to a particularly preferred embodiment the optical window extends across a plurality of optoelectronic functional regions.

Moreover, in a portion of the electrically coupling window that is preferably arranged laterally adjacent to the optically functional region an electrical wiring of a metallization structure (or components of a metal aperture) may extend, cf. claim 13.

Further embodiments are defined in the dependent claims and are also explained in the following detailed description.

Further embodiments are put forward in the following detailed description, while referring to the drawings, which serve to illustrate preferred embodiments in an exemplary and highly schematic manner without being read into the claims based on the concrete statements and announcements, if more general terms are used therein. In the following like or similar components are denoted by the same reference signs throughout the drawings.

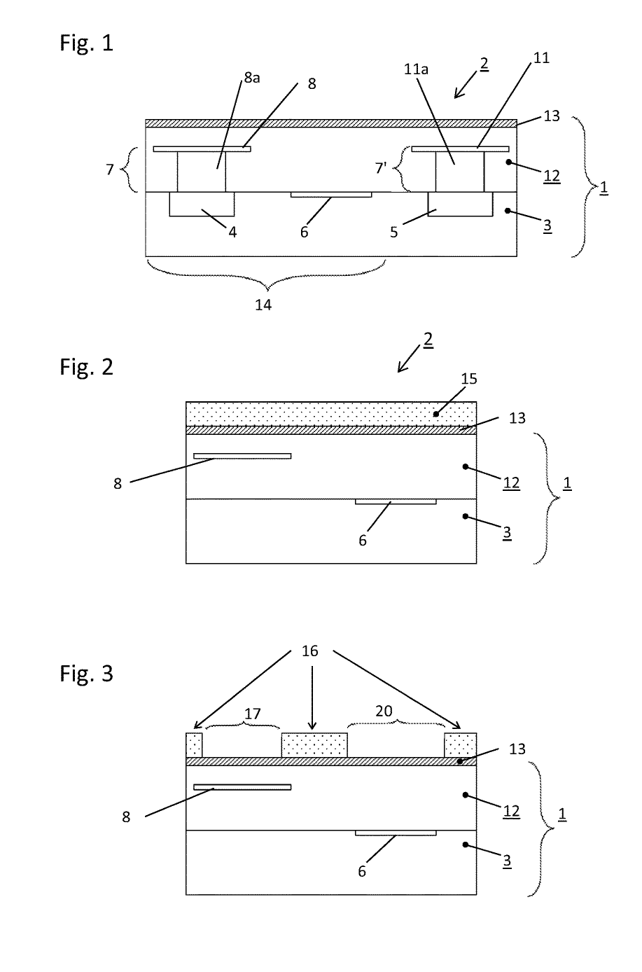

FIG. 1 is a schematic view of the layer stack 1 of an optoelectronic semiconductor device 2 according to an embodiment of the invention.

FIG. 2 is a schematic view illustrating a lateral portion 14 of the layer stack of the optoelectronic device of FIG. 1, wherein a sacrificial layer 15 is additionally applied above the layer stack for forming a masking 16 according to one embodiment of the invention.

FIG. 3 is a schematic in view of the layer stack of FIG. 2 after a further step, in which the sacrificial layer has been patterned into a mask 16 according to one embodiment of the invention.

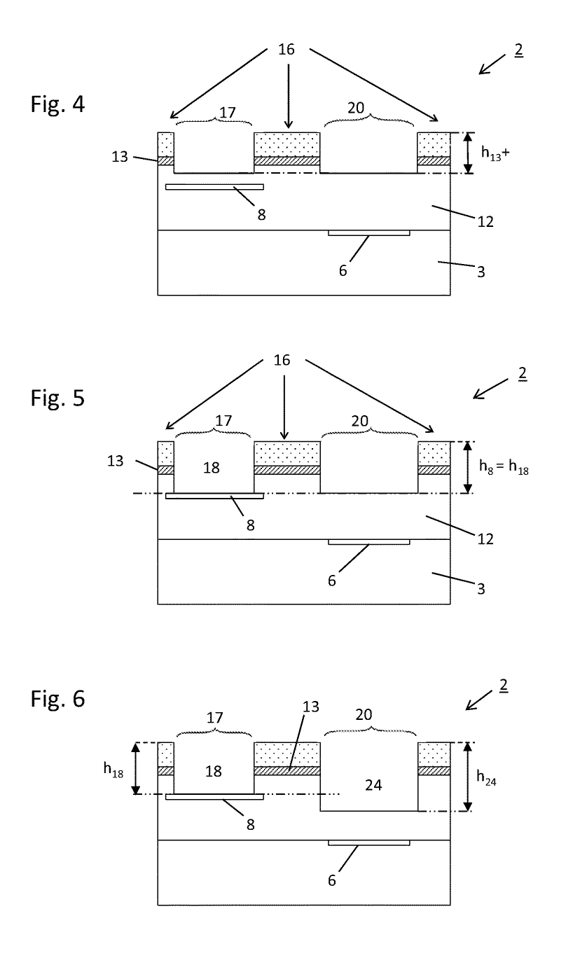

FIG. 4 is a schematic view of the masked layer stack of FIG. 3 in an intermediate state during at process in regions 17 and 20 according to one embodiment of the invention.

FIG. 5 is a view of the masked layer stack of FIGS. 3 and 4 in a further advanced intermediate state during the etching, wherein the etching has advanced to a depth h₈ (also h₁₈ for the window 18) of a contact region of the metallization structure according to one embodiment of the invention.

FIG. 6 is a view of the masked layer stack of FIGS. 3 to 5 in a still further advanced state after a predefined etch time, thereby forming the optical window 24 having the depth h₂₄ according to one embodiment of the invention.

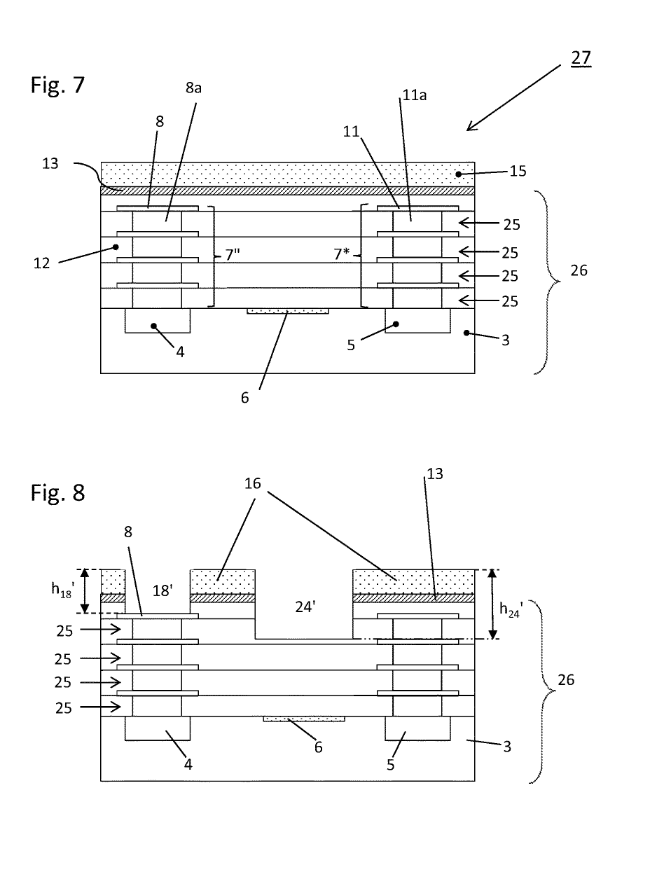

FIG. 7 is a schematic view of an initial state of a further layer stack 26 having a sacrificial layer 15 formed thereon, wherein, contrary to FIG. 1, more details of a multilayer wiring 7″ and 7* are illustrated in the layer stack according to a further embodiment of the invention.

FIG. 8 is a schematic view of the layer stack of FIG. 7 after the patterning, thereby forming a window 24′ of depth h₂₄′ above the optically functional region for optical coupling to the environment, and a further window 18′ of depth h₁₈′ has been formed above the metal 8 according to one embodiment of the invention.

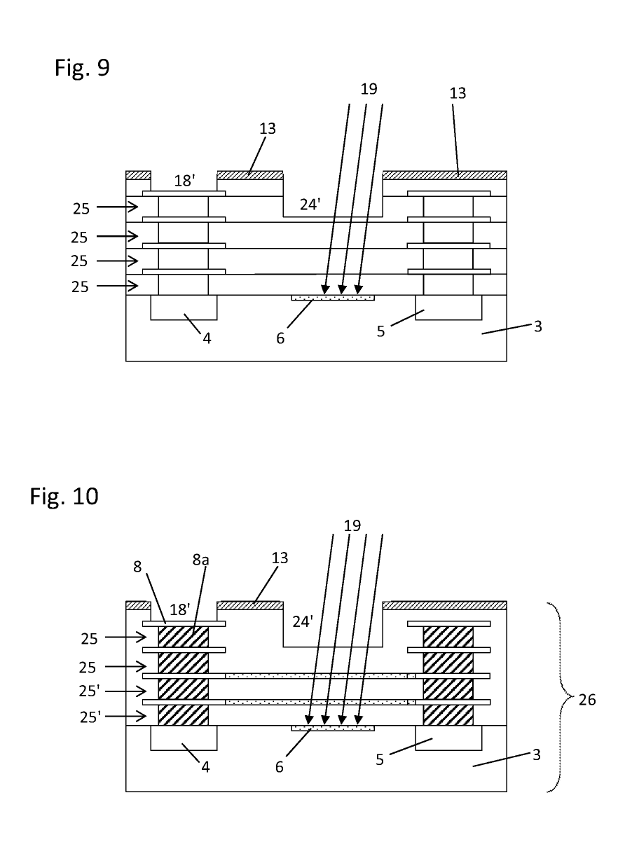

FIG. 9 is a schematic view of an optoelectronic semiconductor device that corresponds to the patterned layer stack of FIG. 8, wherein the sacrificial layer 15 has been removed.

FIG. 10 is a schematic view of an optoelectronic semiconductor device, wherein, contrary to FIG. 9, the two lower metal layers 25′ of the metallization structure 7″ and 7* extend to the optical window 24′.

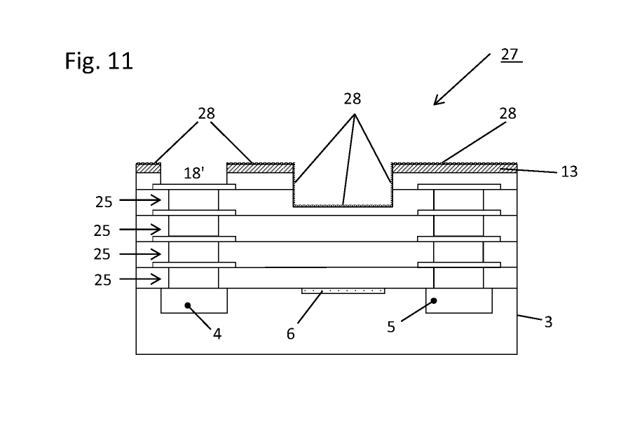

FIG. 11 is a schematic view of an optoelectronic semiconductor device including a window 24 above a light sensitive region 6, wherein within the window and above the semiconductor device a thin additional passivation layer 28 has been formed according to one embodiment of the invention.

FIG. 1 illustrates a schematic view of a layer stack 1 of an optoelectronic semiconductor device 2 according to a first embodiment. The semiconductor device 2 is arranged on a substrate (not shown) and includes a semiconductor layer 3 having doped regions 4 and 5.

For example, the first doped region 4 may be a source region and the second doped region 5 may be a drain region. Between the doped regions 4 and 5 there is disposed an optoelectronically effective functional region 6. It may be light sensitive for visible light or specifically UV radiation.

The functional region 6 in this embodiment is configured as a UV light sensitive region. By means of UV light sensitive region in particular the conductivity between the doped regions 4, 5 may be controlled by irradiating UV light of a certain light intensity onto the light sensitive region 6. In this manner, for instance a UV light sensor may be realized. Generally, a function similar to a gate may be achieved or may be provided by the light sensitive region 6.

To this end, the semiconductor device 2 includes metallization structures 7 and 7′ spaced apart from each other, which include wirings and electrical contacts. The metallization structures 7, 7′ are adapted depending on the application and the geometrical circumstances of the semiconductor device 2 upon forming the semiconductor device 2. For simplicity FIG. 1 merely illustrates a first contact region 8 connected to the first doped region 4 by a first metallic through-contact 8a as a via (structure 7′), and includes a second contact region 11 connected to the second doped region 5 by a second metallic through-contact 11a as a via (structure 7′). Additionally, the semiconductor device 2 may also include horizontal wirings in the layer or level 8-11 as a component of the metallization structures 7, 7′.

In this case the metallization structures 7 and T are integrated into a dielectric layer 12, which is used for electrical insulation of the remaining layers and the metallization structures. The dielectric layer 12 may preferably be made from SiO₂ or any other conventional materials. Metallization structure 7 is positioned on the left-hand side, structure 7′ is positioned on the right-hand side of the functional region 6.

Moreover, the layer stack 1 includes an upper passivation layer 13 for protecting the layers located below. The passivation layer 13 according to this embodiment is formed from Si₃N₄ that exhibits no or only low light absorption in the visible wavelength range, which, however, strongly absorbs light in the UV range. As illustrated in FIG. 2, the layer stack 1 is provided with a sacrificial layer 15, from which an etch mask is to be formed.

The contact regions 8, 11 should serve the purpose of attaching electrical terminals to the semiconductor device 2, for instance by bonding or by further metallic through-contacts as vias 8a and 11a. To this end, openings (that is “windows”) in the layer(s) stack 1 are formed to the contact regions 8, 11.

FIG. 2 illustrates a schematic view showing a lateral partial section 14 of the layer(s) stack 1 of the optoelectronic semiconductor device 2 of FIG. 1 according to one embodiment of the invention. As shown in FIG. 2, the layer stack 1 has been provided with a sacrificial layer 15, from which an etch mask is to be formed. For simplicity, here only the first contact region 8 and the optoelectronically functional region 6 are illustrated, whereas the second contact region 11, the through-contacts 8a, 11a and the doped regions 4 and 5, already explained above, are no longer illustrated.

The etch mask (pad mask) 16, obtained from layer 15, is used for opening the passivation layer 13 and any layers formed therebelow to the uppermost metal wiring layer in order to allow electrical contact thereof.

Openings of this type are not only formed above areas with metal in the uppermost wiring level, but also in areas having a desired light in-coupling. Since the etching stops at a deeper position in the silicon oxide insulation stack, the result is that no strongly UV absorbing layer is present above the light sensitive regions of the CMOS circuit.

In the following description further steps of embodiments of the invention are illustrated, by which a window for electromagnetic radiation above the functional region 6 as well as a passage to the contact regions, for instance contact region 8, are formed.

FIG. 3 illustrates a schematic view of the layer stack 1 of FIG. 2 after a further step, in which the sacrificial layer 15 has been patterned into the mask 16 according to one embodiment of the invention. In this state, for example, the sacrificial layer 15 is prepared as an etch mask 16 for the following process steps. This may be accomplished by a photolithography procedure. The etch mask is appropriately modified, which is initially provided for forming a window (as a passage) located in a first region 17 to the exemplary contact region 8 and which is provided with a corresponding opening. In this manner, the etch mask 16 now additionally has an opening for a second window to be formed in a second region 20 after the modification, through which the functional region 6 buried in the layer stack 1 is coupled to the environment.

FIG. 4 illustrates a schematic view of the masked layer stack 1 of FIG. 3 in an intermediate state during the etch process according to one embodiment of the invention. As illustrated in FIG. 4, the window (the passage) in the region 17 and the window 24 in the region 20 have a depth h₁₃₊, at which the passivation layer 13 has been opened and already a certain amount of material of the dielectric layer 12 has been removed. However, neither the left window nor the right window is “completed” with respect to the depth to be finally reached.

FIG. 5 illustrates a schematic view of the masked layer stack 1 of FIGS. 3 and 4 in a still further advanced etch state, wherein the etching has been performed to a depth h₈ to the surface of the contact region 8 of the metallization structure 7 according to one embodiment of the invention. Since, on the one hand, the etching of the window or passage 18 is performed in the region 17 to the contact region 8 and, on the other hand, the etching of the window 24 is performed in the region 20 to the optoelectronically functional region 6 on the basis of an etch process that is up to this point a common process, the passage 18 in the region 17 and the window 24 in the region 20 have substantially the same depth h₈ or h₁₈ in this state of the process with regard to the window 18 that is completed with respect to the final depth.

FIG. 6 illustrates a schematic view of the masked layer stack 1 of FIGS. 3 to 5 in a still further advanced etch state after expiration of a predefined etch time according to one embodiment of the invention. According to the embodiment illustrated here a selective etch process was selected regarding the material of the contact region 8 of the metallization structure 7 so that the etching stops or has stopped in the region 17 at the contact region 8, whereas in the region 20 the etching still continues. After expiration of a given or “predetermined” etch time the window 24 has reached the intended depth h₂₄, at which also the etching for the optical window is stopped.

Thereafter the sacrificial layer 15 obtained from the etch mask 16 may be removed.

FIG. 7 illustrates a schematic view of an initial state of a further layer(s) stack 26 of a further semiconductor device 27 according to a further embodiment of the invention. As illustrated in FIG. 7, the layer stack 26 is provided with a sacrificial layer 15. Contrary to FIG. 1, in this layer stack 26 several layers or levels 25 of the metallization structure 7″ (left-hand side) and 7* (right-hand side) are used at both sides of the functional region 6, thereby facilitating more complex wirings. The contact pad or the contact region 8 is stacked several times at the left-hand side and is respectively contacted through a via 8a to next deeper level 25. The same holds true for the multilayer system 25 at the right-hand side, which includes contact regions 11 and via 11a, and this holds true for a plurality of metallization layers or levels 25.

FIG. 8 illustrates a schematic view of the layer stack 26 of FIG. 7 after the steps of patterning and etching, thereby forming a passage 18′ to the contact region 8 of the uppermost metal layer and a window 24′ for electromagnetic radiation, in particular for UV light, in a region 20 above the optoelectronically functional region 6. The depth of window 18′ is h₁₈′.

In the pad level an opening in the resist mask was formed above the optically sensitive region 6 by means of photolithography so that the subsequent pad etching in this region and at each pad, that is, at each contact region 8, removes the passivation layer 13 as well as respective subsequent dielectric insulation layers. Here, the pad etching stops upon reaching the metallic pads (contact region 8) and after a short over-etch time. Since the preferably UV sensitive region 6 does not include metallic structures, a recess h₂₄′ is obtained that extends below the uppermost metal layer.

In order to guarantee that no metal is encountered in the region 20 of the window 24′ also the second uppermost metal is forbidden in the entire region 20 of the corresponding mask openings.

In a four-metal layer process therefore metal traces of the first and at most of the second metal layers 25 may be light emitting below the UV window 24′, but metal traces of the third and fourth (uppermost) metal layers 25 will not be capable of emitting light. Preferably, h₂₄′ terminates below the first metal layer 8 and in front of (or above) the second metal layer, it is, however, deeper than the etch depth h₁₈ that reaches to the contact region 8 (left-hand side). This corresponds to the result of FIG. 6 for the one-layer metal level.

FIG. 9 illustrates a schematic view of an optoelectronic semiconductor device 27 that corresponds to the patterned layer stack 26 of FIG. 7 or 8, wherein the sacrificial layer 15 (its mask residue 16) has been removed. As illustrated in FIG. 9 light or UV light 19 may be incident through the window 24′ in the region 20 onto the functional region 6, wherein absorption and reflection are now reduced.

FIG. 10 illustrates a schematic view of a comparable optoelectronic semiconductor device 27, wherein, contrary to FIG. 9, the two lower metal layers 25′ of the four-layer metallization structure 7 and 7′ extend within the window 24′.

Since the UV window 24′ may extend across several UV sensitive regions 6 coupling in of light is accomplished as homogeneous as possible, wherein even the electric wiring or metal apertures may be provided within the UV window 24′. Among others, this allows the provision of filters on the wafer for modifying the incident light spectrum without negative effect of the steep steps at the edge of the UV window on the sensor performance, since these regions may be formed at a far distance with respect to the UV sensitive regions 6.

FIG. 11 is a schematic view of an optoelectronic semiconductor device 27 including a window 24′ above a light sensitive region 6, wherein a thin additional passivation layer 28′ has been applied in the window 24′ and above the semiconductor device 26 according to a further embodiment.

According to this embodiment, after exposing the region by etching an additional Si₃N₄ layer 28 is deposited for the window 24′ and the region 17 above the contact region 8 in this manner. This layer is patterned by means of an additional mask (not shown), thereby removing the layer in the region 17 of the contact region 8 and thus allowing the final chip to be electrically contacted.

In this manner, the passivation protection of the semiconductor device 27 is also achieved in the deeply etched region 20 of the window 24′ above the functional region 6, wherein the thickness of the passivation layer 28 deposited and the associated absorption may specifically be reduced by an order of magnitude compared to the original first passivation layer 13.

1. A method for fabricating an optoelectronic semiconductor device (2, 27), comprising the steps of:
providing a layer stack (1, 26) including at least one metallization structure (7, 7′) that includes at least one contact region (8, 11) for electrically contacting the semiconductor device (2, 27);
said layer stack (26) including at least one dielectric layer (12) and at least one semiconductor layer (3), wherein the semiconductor layer (3) includes at least one functional region (6) configured as an interface for electromagnetic radiation; and
stripping or removing material of the layer stack (1, 26) by a common stripping or removal in local regions (17, 20) above the at least one contact region (8) and above the functional region (6);
thereby exposing or forming two differently deep windows (18, 24; 18′, 24′) for coupling the semiconductor device (2, 27) to an environment.

2. The method according to claim 1, wherein the metallization structure (7, 7′) is integrated into the dielectric layer (12) such that the dielectric layer (12) above the at least one functional region (6) is recessed more deeply (h₂₄′, h₂₄) by said stripping or removing as compared to the local region (17) above the contact region (8).

3. The method according to claim 1, wherein a mask (16) is applied above the layer stack (1, 26) and the local stripping or removing is performed by using the mask (16).

4. The method according to claim 3, wherein the mask (16) is formed by at least one of a photolithography process and a modification of an etch mask (16) provided for exposing the contact region (8, 11).

5. (canceled)

6. The method according to claim 1, further comprising:
forming a further passivation layer (28) above the layer stack (26), said further passivation layer reaching into the region (20) exposed above the functional region (6) and into the exposed region (17) above the contact region (8);
removing the further passivation layer (28) in part within the region (17) that was exposed above the contact region (8).

7. The method according to claim 1, wherein the functional region (6) of the semiconductor layer (3) comprises at least one of a light emitting region and a light sensitive region.

8. The method according to claim 1, wherein the layer stack (1, 26) including the at least one metallization structure is provided with a multilayer wiring (7″, 7*).

9. An integrated circuit structure comprising a plurality of semiconductor devices (2, 27) and respective an associated optoelectronic interface (6) for coupling the integrated circuit structure to an environment, the semiconductor devices (2, 27) being produced by:
providing a layer stack (1, 26) including at least one metallization structure (7, 7′) that includes at least one contact region (8, 11) for electrically contacting the semiconductor device (2, 27);
said layer stack (26) including at least one dielectric layer (12) and at least one semiconductor layer (3), wherein the semiconductor layer (3) includes at least one functional region (6) configured as an interface for electromagnetic radiation; and
stripping or removing material of the layer stack (1, 26) by a common stripping or removal in local regions (17, 20) above the at least one contact region (8) and above the functional region (6);
thereby exposing or forming two differently deep windows (18, 24; 18′, 24′) for coupling the semiconductor device (2, 27) to an environment.

10. The circuit structure according to claim 9, wherein the plurality of semiconductor devices (2, 27) forms a CMOS structure.

11. The circuit structure according to claim 9, wherein the interfaces comprise a window (24, 24′) formed by etching whose lateral extension is greater in at least one direction by at least one of a predefined factor and a predefined amount than a lateral extension of a respective optoelectronically functional region (6) below the respective interface of the respective semiconductor device (2, 27).

12. The circuit structure according to claim 9, wherein a window (24, 24′) formed by one of stripping or removing extends across a plurality of the optoelectronically functional regions (6).

13. The circuit structure according to claim 11, wherein at least one of an electric wiring of a metallization structure (7, 7′, 7″, 7*) and components of a metal aperture extends into an area laterally adjacent to at least one of the functional region (6) and the window (24) or is placed therein.

14. A semiconductor device (2, 27) having optoelectronic properties, said semiconductor device being produced by:
providing a layer stack (1, 26) including at least one metallization structure (7, 7′) that includes at least one contact region (8, 11) for electrically contacting the semiconductor device (2, 27);
said layer stack (26) including at least one dielectric layer (12) and at least one semiconductor layer (3), wherein the semiconductor layer (3) includes at least one functional region (6) configured as an interface for electromagnetic radiation; and
stripping or removing material of the layer stack (1, 26) by a common stripping or removal in local regions (17, 20) above the at least one contact region (8) and above the functional region (6);
thereby exposing or forming two differently deep windows (18, 24; 18′, 24′) for coupling the semiconductor device (2, 27) to an environment.

15. The method according to claim 1, wherein the etching is selective and is performed for a predefined etch time that is selected such that the etching ends at the contact region (8) after a time period that is shorter than the predefined etch time and the etching continues in the region (2) located above the at least one functional region (6).

16. The method according to claim 1, wherein the stripping or removal of the layer stack (1, 26) is performed by etching.

17. The method according to claim 16, wherein the layer stack (1, 26) comprises a passivation layer (13) that is opened by the etching.

18. The method according to claim 5, wherein the passivation layer (13) is formed from silicon nitride.

19. The method according to claim 7, wherein the light sensitive region comprises a UV light sensitive region.

20. The integrated circuit structure of claim 9, wherein the stripping or removal of the layer stack (1, 26) is performed by etching, the etching being selective and being performed for a predefined etch time that is selected such that the etching ends at the contact region (8) after a time period that is shorter than the predefined etch time and the etching continues in the region (2) located above the at least one functional region (6).

21. The semiconductor device (2, 27) of claim 14, wherein the stripping or removal of the layer stack (1, 26) is performed by etching, the etching being selective and being performed for a predefined etch time that is selected such that the etching ends at the contact region (8) after a time period that is shorter than the predefined etch time and the etching continues in the region (2) located above the at least one functional region (6).
